(19) United States
(12) Patent Application Publication
(10) Pub. No.: US 2004/0071863 A1
(43) Pub. Date: Apr. 15, 2004

(54) Methods for forming coatings on MEMS devices

(76) Inventors: Xiaoyang Zhu, Maple Grove, MN (US); Yongseok Jun, Minneapolis, MN (US); Hongwei Yan, St. Paul, MN (US)

Correspondence Address: MUETING, RAASCH & GEBHARDT, P.A., P.O. BOX 581415, MINNEAPOLIS, MN, 55458, US

(21) Appl. No.: 10/269,682

(22) Filed: Oct. 11, 2002

(51) Int. Cl. B05D 5/12; C23C 16/00

(52) U.S. Cl. 427/58; 427/248.1

(57) ABSTRACT

A chemical approach for the attachment of molecules on a surface of a MEMS device, preferably, to provide a monolayer film thereon of relatively low surface energy.

### STATEMENT OF GOVERNMENT RIGHTS

This work was supported in part by Sandia National Laboratory under contract number BE-7471. The government may have certain rights in the invention.

### BACKGROUND OF THE INVENTION

This invention deals with modifying surfaces of microelectromechanical system (MEMS) devices, also called micromachines or microsystems. More particularly, the invention deals with forming low energy coatings on MEMS devices.

One of the barriers to full commercialization of MEMS is reliability. Among a number of process related issues, the difficulty in controlling surface forces is an impediment to the fabrication and operation of MEMS devices. This is a consequence of the scaling law. The surface-area to volume ratio scales with the inverse of device dimension. As a result, surface forces can lead to reliability problems, including stiction and drift. Stiction occurs when the surface adhesion force overcomes the mechanical restoring force of microstructures. This is a particularly significant problem for surface micromachined devices. Drift in device performance, such as electrostatic driving voltage, can also result from surface forces. Adsorption of background molecules onto the high-energy surface of microstructures can change the dielectric constant and, more importantly, surface stress. The solution to both stiction and drift problems is to apply a low energy, passivation coating to the surfaces of MEMS devices.

One known method of applying a low energy coating involves forming an oriented monolayer that includes —COOH and —CF₃ end groups attached to the surface of a MEMS device during the packaging stage. However, due to the weak bonding between the —COOH group and the surface, the monolayer is susceptible to moisture attack, thermal decomposition, or evaporation. These necessitate the use of hermetically sealed packages. The perfluorocarboxylic acid molecule is also corrosive towards some materials commonly used in MEMS devices. Thus, the use of such compounds during the packaging process to coat a surface of a MEMS device is undesirable for some MEMS products. Furthermore, coating a surface of a MEMS device during the packaging process is typically limited with respect to the processing conditions (e.g., elevated pressures cannot typically be used).

Another known method involves introducing moisture or moisture plus organic material into a package and heating the package to a high temperature to form a passivation coating on the surface of a MEMS device. The application of a coating only at the packaging stage puts limitations on the chemistry used. Herein, “package” or “packaging” refers to those typically used in MEMS products, including the gold wire sealed hermetic package used in Digital Light Processing (DLP) products of Texas Instruments, the ceramic dual in-line package (CERDIP) used in accelerometer products of Analog Devices, Inc., and other common packages, such as Ceramic SOIC, CERPAC, Ceramic or plastic PGA Packages, etc.

Also, a number of publications (see, e.g., R. Maboudian, Surf Sci. Rep., 1998, 30, 207-269) teach the use of siloxane self-assembled monolayers (SAMs) formed from solutions of alkyltrichlorosilane or trialkoxylsilanes as passivation coatings for MEMS, but difficulties associated with irreproducibility and the easy formation of polymeric and other microstructures can make siloxane SAMs undesirable (see, e.g., Bunker, et al. Langmuir, 2000, 16, 7742-7751).

Thus, there is a need for additional methods for modifying MEMS devices, particularly to form low energy surfaces, preferably those having low energy monolayers as passivating coatings. Desirably, this would be accomplished before the packaging stage of a MEMS device. The advantages of coating before packaging include the versatility of coating chemistry (e.g., gas or liquid based reactions, high or low pressures) and the feasibility of extensive testing before packaging. There is also a need to form conformal layers, preferably monolayers, preferably without the complication of forming polymeric or other microstructures.

### SUMMARY OF THE INVENTION

The present invention provides methods for the formation of coatings, particularly passivation coatings, on MEMS devices. Preferably, the surface modifications occur before the packaging stage of the device. Preferably, the methods can be used to form monolayer, conformal coatings. Such coatings desirably form low energy surfaces.

In one embodiment, there is provided a method of applying a coating to a surface of a MEMS device that includes: contacting the surface of the MEMS device with one or more precursor compounds of the formula SiXR₃, wherein each R is independently an organic group, and X is independently selected from the group of Cl and OR′, wherein R′ is independently an alkyl group; and further wherein the one or more precursor compounds are in solution at a temperature of at least about 80° C. upon contacting the surface of the MEMS device. Preferably, the one or more precursor compounds are in solution at a temperature of about 80° C. to about 300° C. upon contacting the surface of the MEMS device.

In one embodiment, there is provided a method of applying a coating to a surface of a MEMS device that includes: contacting the surface of the MEMS device with one or more precursor compounds of the formula SiXR₃, each R is independently an organic group, and X is independently selected from the group consisting of Cl and OR′, wherein R′ is independently an alkyl group; and further wherein the one or more precursor compounds are in a vapor phase prior to contacting the surface of the MEMS device.

In one embodiment, there is provided a method of applying a coating to a surface of a MEMS device that includes: contacting the surface of the MEMS device with one or more precursor compounds of the formula SiXR₃, wherein each R is independently an organic group, and X is independently selected from the group of Cl and OR′, wherein R′ is independently an alkyl group; and further wherein the contacting step occurs prior to packaging of the MEMS device.

In one embodiment, there is provided a method of applying a coating to a surface of a MEMS device that includes: contacting the surface of the MEMS device with one or more precursor compounds of the formula SiXR₃, wherein each R is independently an organic group, and X is independently selected from the group of Cl and OR′, wherein R′ is independently an alkyl group; and further wherein the coating is a monolayer film.

In one embodiment, there is provided a method of applying a coating to a surface of a MEMS device that includes: contacting the surface of the MEMS device with one or more precursor compounds of the formula SiHₙR₄₋ₙ, wherein n=1-3 and each R is independently an organic group. This method can occur prior to or simultaneously with packaging the MEMS device.

In one embodiment, there is provided a method of applying a coating to a surface of a MEMS device that includes: contacting one or more MEMS devices with one or more precursor compounds in a sealed container prior to packaging the MEMS device. Preferably, the contacting step is carried out under an inert atmosphere.

In one embodiment, there is provided a method of applying a coating to a surface of a MEMS device that includes: contacting one or more MEMS devices with one or more precursor compounds in a sealed container prior to packaging the MEMS device, wherein the contacting step is carried out at a pressure of more than 1 atm.

In one embodiment, there is provided a method of applying a coating to a surface of a MEMS device that includes: contacting one or more MEMS devices with one or more precursor compounds in a sealed container prior to packaging the one or more MEMS devices, wherein the one or more precursor compounds are in a vapor phase prior to contacting the one or more MEMS devices.

In one embodiment, there is provided a method of applying a coating to a surface of a MEMS device that includes: contacting one or more MEMS devices with one or more precursor compounds in a sealed container prior to packaging the one or more MEMS devices, wherein the one or more precursor compounds are in solution at a temperature of about 80° C. to about 300° C. upon contacting the one or more MEMS devices.

In one embodiment, there is provided a method of applying a coating to a surface of a MEMS device that includes: contacting one or more MEMS devices with one or more precursor compounds in a sealed container prior to packaging the one or more MEMS devices, wherein the one or more precursor compounds are of the formula SiXₙR₄₋ₙ, wherein n=1-3, each R is independently an organic group, and each X is independently selected from the group consisting of H, Cl, and OR′, wherein each R′ is independently an alkyl group.

In one embodiment, there is provided a method of applying a coating to a surface of a MEMS device that includes: contacting one or more MEMS devices with one or more precursor compounds in a sealed container prior to packaging the one or more MEMS devices, wherein the one or more precursor compounds are of the formula SiXR₃, wherein each R is independently an organic group, and each X is independently selected from the group of Cl and OR′, wherein each R′ is independently an alkyl group.

In one embodiment, there is provided a method of applying a coating to a surface of a MEMS device that includes: contacting one or more MEMS devices with one or more precursor compounds in a sealed container prior to packaging the more or more MEMS devices, wherein the one or more precursor compounds are of the formula SiHₙR₄₋ₙ, wherein n=1-3 and each R is independently an organic group.

In one embodiment, there is provided a method of applying a coating to a surface of a MEMS device that includes: contacting one or more MEMS devices with one or more precursor compounds in a sealed container prior to packaging the one or more MEMS devices, wherein the precursor compounds are selected from the group consisting of silanes, siloxanes, organic phosphates, alcohols, ketones, aldehydes, alkenes, alkynes, and combinations thereof.

Herein, in the description of these methods “a” and “the” are generally used interchangeably with “at least one” and “one or more.”

Other objects, features, and advantages of the present invention will become apparent from the following detailed description. It should be understood, however, that the detailed description and specific examples, while indicating preferred embodiments of the invention, are given by way of illustration only. Various changes and modifications within the spirit and scope of the invention will be apparent to those skilled in the art.

### BRIEF DESCRIPTION OF THE DRAWINGS

FIG. 1. Schematic illustration of the coating process with organic vapor.

FIG. 2. Schematic illustration of the coating process in solution or a supercritical state.

FIG. 3. Atomic Force Microscope image of a Si(111) surface after coating with phenylsilane.

FIG. 4. Fourier Transform Infrared Spectrum of a Si(111) surface after coating with phenylsilane.

FIG. 5. Water contact angles as a function of annealing temperature in air (open circles) and nitrogen (closed circles) for monolayer coating (1b) on the native oxide terminated Si(111) surface. The coating was obtained according to FIG. 1 using dimethyl(perfluorooctyl)silane as the precursor molecule.

### DETAILED DESCRIPTION OF PREFERRED EMBODIMENTS OF THE INVENTION

The present invention provides methods of modifying a surface of a MEMS device. Preferably, such methods form low energy films (i.e., coatings) thereon, which are typically in the form of monolayer films. In this context, “low energy” means the water contact angle of the surface is larger than 90 degrees.

Such coatings (i.e., films) preferably form passivation layers. In this context, a passivation layer is one that possesses generally low chemical reactivity (for example, the surface does not typically allow the chemisorption of and/or the reaction with oxygen and water molecules). The low energy coatings are preferably thermally stable up to temperatures as high as 400° C., for example. Preferably, coatings of the present invention can be used to eliminate stiction or performance drift in MEMS devices, for example.

Generally, the monolayer film has a substantially molecular thickness, and the molecules of the monolayer are substantially close-packed, such that the molecules are at or near van der Waals radii from each other. The molecules forming the monolayer are preferably chemically and thermally stable at room temperature (with vaporization temperatures preferably above room temperature, and more preferably below 400° C.), and are preferably soluble in an organic solvent such as iso-octane in an amount of at least about 1×10⁻⁶ mole/liter.

Various surfaces of MEMS devices may be modified according to the present invention using organic precursor molecules. The various surfaces of MEMS devices can include a variety of metals (which term is used herein to include metalloids or semimetals, particularly silicon, gold, aluminum, a lanthanide, etc.), metal oxides, metal nitrides, metal carbides, or combinations thereof. The metal-containing surfaces (e.g., whether they are in the form of pure metals, metal oxides, metal nitrides, metal carbides, etc.) can be in the form of semiconductor and ceramic materials. Preferably, the surface includes silicon (e.g., silicon, silicon oxide, silicon nitride, silicon carbide). Most preferably, the surface selected for modification according to the present invention is a silicon surface, a silicon oxide surface, a silicon nitride surface, or combinations thereof, which are the typical materials used in MEMS devices.

Each organic precursor molecule used in the coating process is preferably selected to contain two major parts: a functional group to provide low surface energy (e.g., a “wax-like” or “Teflon-like” surface); and a second reactive group to selectively attach to the solid surface of interest. Typically, the reaction self-terminates after a saturated monolayer coverage is reached. Intermolecular cross-linking and polymerization are avoided by choosing molecules with a single reactive group for attachment, such as perfluorodecyl 1H, 1H, 2H, 2H-dimethylchlorosilane, or molecules with multiple functionalities but reduced reactivity, which limits the possibility of crosslinking. An example for the latter is phenylsilane (C₆H₅SiH₃). Once attached to the surface, crosslinking between neighboring molecules to form Si—Si bond is generally unlikely due to geometric restrictions.

In a preferred embodiment of the present invention, the organic groups attached (typically and preferably) covalently bonded to the surface forming the film are straight chain alkyl groups, which preferably form a passivation layer. Such passivation layers are particularly useful for microelectromechanical systems (MEMS). These straight chain alkyl groups can be of any length desired for the particular application and are preferably fully fluorinated or partially fluorinated with CF₃ termination. In another preferred embodiment of the present invention, the molecules covalently bonded to the surface forming the film are molecules that include aromatic groups.

As used herein, the term “organic group” means a hydrocarbon group (with optional elements other than carbon and hydrogen, such as oxygen, nitrogen, sulfur, and silicon) that is classified as an aliphatic group, cyclic group, or combination of aliphatic and cyclic groups (e.g., alkaryl and aralkyl groups). In the context of the present invention, the organic groups are those that do not interfere with the formation of a film on a MEMS device, preferably a low energy film. Preferably, they are of a type and size that do not interfere with the formation of a low energy monolayer film. The term “aliphatic group” means a saturated or unsaturated linear or branched hydrocarbon group. This term is used to encompass alkyl, alkenyl, and alkynyl groups, for example. The term “alkyl group” means a saturated linear or branched hydrocarbon group including, for example, methyl, ethyl, isopropyl, t-butyl, heptyl, dodecyl, octadecyl, amyl, 2-ethylhexyl, and the like. The term “alkenyl group” means an unsaturated, linear or branched hydrocarbon group with one or more carbon-carbon double bonds, such as a vinyl group. The term “alkynyl group” means an unsaturated, linear or branched hydrocarbon group with one or more carbon-carbon triple bonds. The term “cyclic group” means a closed ring hydrocarbon group that is classified as an alicyclic group, aromatic group, or heterocyclic group. The term “alicyclic group” means a cyclic hydrocarbon group having properties resembling those of aliphatic groups. The term “aromatic group” or “aryl group” means a mono- or polynuclear aromatic hydrocarbon group. The term “heterocyclic group” means a closed ring hydrocarbon in which one or more of the atoms in the ring is an element other than carbon (e.g., nitrogen, oxygen, sulfur, etc.).

Substitution is anticipated on the organic groups of the complexes of the present invention. As a means of simplifying the discussion and recitation of certain terminology used throughout this application, the terms “group” and “moiety” are used to differentiate between chemical species that allow for substitution or that may be substituted and those that do not allow or may not be so substituted. Thus, when the term “group” is used to describe a chemical substituent, the described chemical material includes the unsubstituted group and that group with O, N, Si, or S atoms, for example, in the chain (as in an alkoxy group) as well as carbonyl groups or other conventional substitution. Where the term “moiety” is used to describe a chemical compound or substituent, only an unsubstituted chemical material is intended to be included. For example, the phrase “alkyl group” is intended to include not only pure open chain saturated hydrocarbon alkyl substituents, such as methyl, ethyl, propyl, t-butyl, and the like, but also alkyl substituents bearing further substituents known in the art, such as hydroxy, alkoxy, alkylsulfonyl, halogen atoms, cyano, nitro, amino, carboxyl, etc. Thus, “alkyl group” includes ether groups, haloalkyls, nitroalkyls, carboxyalkyls, hydroxyalkyls, sulfoalkyls, etc. On the other hand, the phrase “alkyl moiety” is limited to the inclusion of only pure open chain saturated hydrocarbon alkyl substituents, such as methyl, ethyl, propyl, t-butyl, and the like.

A wide variety of precursor compounds can be used in the various embodiments of the invention to modify surfaces of MEMs devices. The precursor compounds are preferably in liquid form at room temperature. More preferably, the precursor compounds are those that can be used at elevated pressures (i.e., a pressure above 1 atmosphere).

Suitable precursor compounds include silanes, siloxanes, organic phosphates, etc. Examples include those disclosed in U.S. Pat. No. 5,694,740 (Martin et al.). In addition to silanes, siloxanes, and organic phosphates, when the MEMS device includes Si—H groups (as occurs upon HF etching, for example), the precursor compounds can also be selected from alcohols, ketones, aldehydes, alkenes, and alkynes. Various combinations of such precursor compounds can be used in the methods of the present invention.

Preferably, the surfaces are modified by silicon precursor compounds containing organic groups. Preferably, the silicon precursor compounds include at least one of hydrogen, chlorine, and an alkoxide group (including combinations thereof).

For certain embodiments, preferred organic precursor compounds are of the general formula SiXₙR₄₋ₙ(Formula I), wherein n=1-3, each R is independently (i.e., the same or different) an organic group, and each X is independently selected from the group of H, Cl, and OR′, wherein each R′ is independently an alkyl group thereby forming an alkoxyl group. Preferably, each R and R′ in Formula I independently includes 1-20 carbon atoms (and for certain embodiments, 2-20 carbon atoms). More preferably, at least one R in Formula I includes up to 20 carbon atoms, while the others include up to 2 carbon atoms. More preferably, each R′ in Formula I independently is a C1-C4 alkyl moiety.

For certain embodiments, more preferred organic precursor compounds are of the general formula SiXR₃ (Formula II), wherein each R is independently (i.e., the same or different) an organic group, and X is independently selected from the group of Cl and OR′, wherein R′ is independently an alkyl group thereby forming an alkoxyl group. Preferably, each R and R′ in Formula II independently includes 1-20 carbon atoms (and for certain embodiments, 2-20 carbon atoms). More preferably, at least one R in Formula II includes up to 20 carbon atoms, while the others include up to 2 carbon atoms. More preferably, each R′ in Formula II independently is a C1-C4 alkyl moiety. Examples of these precursor molecules include monochlorosilanes (R₃SiCl) and monoalkoxylsilanes (R₃SiOR′). Such compounds are particularly desirable because they more readily form monolayers.

For certain embodiments, even more preferred organic precursor compounds are of the general formula SiHₙR₄₋ₙ, (Formula III), wherein n=1-3, each R is independently (i.e., the same or different) an organic group. Preferably, each R in Formula III independently includes 1-20 carbon atoms. More preferably, at least one R in Formula III includes up to 20 carbon atoms, while the others include up to 2 carbon atoms. Such hydride-containing precursor compounds typically have reduced reactivity as compared to chlorides and alkoxides.

For certain embodiments, at least one R in Formulas I-III is a fluorinated aliphatic group. Preferably, at least one R in Formulas I-III is at least partially fluorinated with CF₃ termination. More preferably, at least one R in Formulas I-III is fully fluorinated (i.e., perfluorinated). For certain other embodiments, at least one R in Formulas I-III is an aromatic group having at least 6 carbon atoms, preferably no more than 20 carbon atoms, and more preferably no more than 12 carbon atoms, and most preferably R is phenyl. The aromatic groups can optionally include one or more fluorine atoms.

In a particular embodiment, a microelectromechanical system is formed that includes the surface of the present invention. There are many types of MEMS devices. They can include, for example, optical routing devices, digital mirror devices, pressure sensors, optical grating devices, and the like. Such devices are generically disclosed in U.S. Pat. Nos. 5,694,740 (Martin et al.) and 5,602,671 (Hornbeck); Proceeding of the 7^{th} International Conference on the Commercialization of Micro and Nano Systems; Hsu, Tai-Ran—MEMS and Microsystems: design and manufacture (McGraw-Hill, c2002.); and W. Menz, J. Mohr, O. Paul, Microsystem technology (Wiley-VCH, New York, 2001).

The apparatus used in the coating process is typically a sealed container, preferably a high pressure reactor, such as that offered by Parr Instrument Company, (Moline, Ill.). One or more MEMS device, can be placed in the sealed reactor, along with one or more neat organic precursor compounds or solutions of organic precursor compounds. Such solutions can include a wide variety of organic solvents, including alkanes (e.g., isooctane, hexane), alcohols (e.g., ethanol, isopropylalcohol), ketones (e.g., acetone), ethers (e.g., tetrahydrofuran), etc.

The reaction is preferably carried out under an inert atmosphere, e.g., nitrogen or argon gas. In one embodiment, a catalyst may be added to the container to facilitate the surface attachment reaction. Examples of these catalysts include oxidizing catalysts (e.g., water, oxygen, and peroxides) for silicon-hydride (Si—H) containing precursor compounds, and organic bases (e.g., pyridine and trialkylamines), for silicon-chloride (Si—Cl) containing precursor compounds, etc.

The temperature of the reaction (which is the temperature of the surface of the MEMS device on which the reaction is occurring or the equilibrium temperature of the system in which the MEMS device is located) is one that is sufficient to enable surface reaction between the organic precursor compound(s) and the MEMS device(s). The temperature is preferably at least about 25° C., more preferably at least about 80° C., and even more preferably at least about 100° C. Typically and preferably, the temperature is no more than about 400° C., and more preferably, no more than about 300° C.

The pressure of precursor compounds in the reactor is one that is sufficient to enable surface reaction between the organic precursor compound(s) and the substrate(s) (e.g., MEMS device). The pressure is preferably at least about 1×10⁻³ atmospheres (atm), more preferably at least about 1 atm, even more preferably more than about 1 atm (e.g., at least 1.1 atm), even more preferably at least about 2 atm, and most preferably at least about 5 atm. Typically and preferably, the pressure is no more than about 1000 atm, more preferably no more than about 200 atm, and even more preferably, no more than about 20 atm.

In one exemplary embodiment, precursor molecules, which can be one compound or a mixture of compounds, and one or more MEMS device(s) are placed in a container. The container is sealed and the sealed container is preferably heated to temperatures above the boiling temperature of the precursor molecule(s) to enable reaction between the gas phase precursor molecules and the surface of the MEMS device(s).

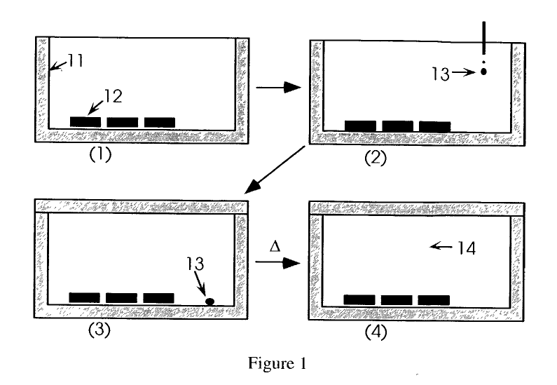

In a particularly preferred embodiment, referring to FIG. 1, MEMS devices [12] are placed in reactor [11]. Organic precursor molecules [13] are added to the reactor and the reactor is subsequently sealed. After heating to a desirable temperature, the organic precursors vaporize to form the vapor [14], which then contacts the MEMS devices.

In another exemplary embodiment, one or more MEMS devices are immersed in a neat liquid or organic solution of one or more precursor compound(s) in a container, sealed, and preferably heated to enable the reaction between the precursor molecules in liquid or solution phase and the surface of the MEMS device(s).

In another exemplary embodiment, one or more MEMS devices are immersed in a neat liquid or organic solution of one or more precursor compound(s) in a container, sealed, and preferably heated under pressure to reach a supercritical state to enable the reaction between the precursor molecules and the surface of the substrate(s). A liquid is said to be in a supercritical state when it is no longer possible to return it to its liquid state by increasing the pressure.

In another exemplary embodiment, one or more MEMS devices are used. These MEMS devices are preferably obtained from liquid etching processes to remove the sacrificial layers, such as aqueous HF release-etch. After a number of steps of liquid substitution to replace aqueous solutions with dry organic solvents, the MEMS devices are transferred to the reactor in the presence of excess organic solvent. A small amount of one or more organic precursor compounds are added to the reactor and the reactor is sealed. The sealed reactor is preferably heated to an elevated temperature to enable the surface reaction between the precursor molecules in the solution (or supercritical state) and the MEMS device(s). The volume of the organic solvent is selected to ensure that, at the reaction temperature, the solvent in the sealed reactor is either in the liquid or the supercritical state. After the reaction, the reactor is cooled down and opened, the coated MEMS devices are removed from the reactor, washed with organic solvents, and dried.

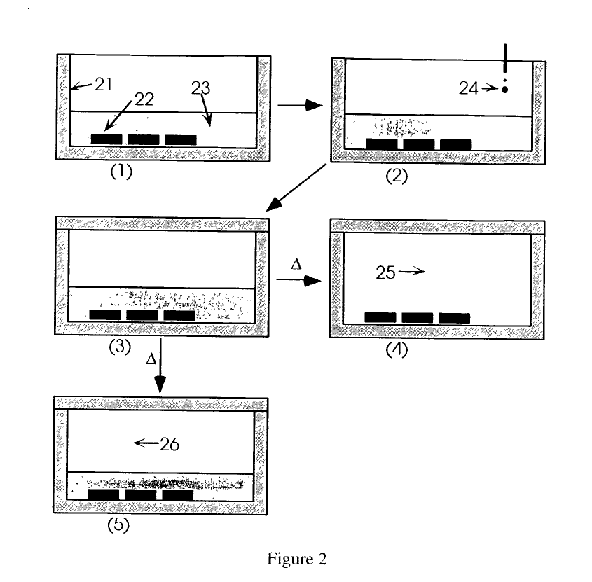

Referring to FIG. 2, MEMS devices [22] obtained from wet etching and solvent exchange are placed in reactor [21] containing organic solvent [23]. Organic precursor molecules [24] are added to the solvent. After sealing the reactor and heating to a desirable temperature, the organic solution is either in a supercritical state [25] or a gas [26] in equilibrium with a liquid state.

For reactions in which the precursor compound(s) react with the surface in the gas phase, typically, the amount of one or more precursor compounds added to the reactor is an amount sufficient for forming a monolayer coating on the surface of the substrate (e.g., MEMS device), but not so much that condensation of the organic molecules occurs after the reaction is completed and the reactor is cooled down to room temperature. Preferably, this involves the use of at least 0.1 mMole (mM) of precursor molecules per liter of reactor volume. Preferably, this involves the use of no more than 10 mM of precursor molecules per liter of reactor.

For reactions in which the precursor compound(s) react with the surface in the liquid phase (e.g., neat or in solution), typically, the amount of one or more precursor compounds added to the reactor is an amount sufficient for forming a monolayer coating on the surface of the substrate (e.g., MEMS device). Preferably, this involves the use of at least 1 mM concentration of precursor molecules.

Typically, these methods are carried out prior to packaging the MEMS devices. However, certain coating methods of the present invention can be carried out during the packaging process. This involves, for example, methods as described in U.S. Pat. No. 5,694,740 (Martin et al.).

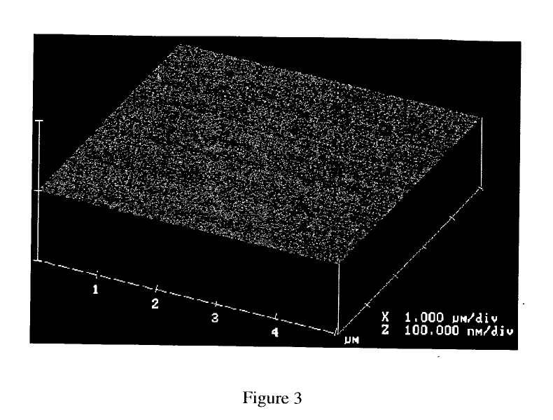

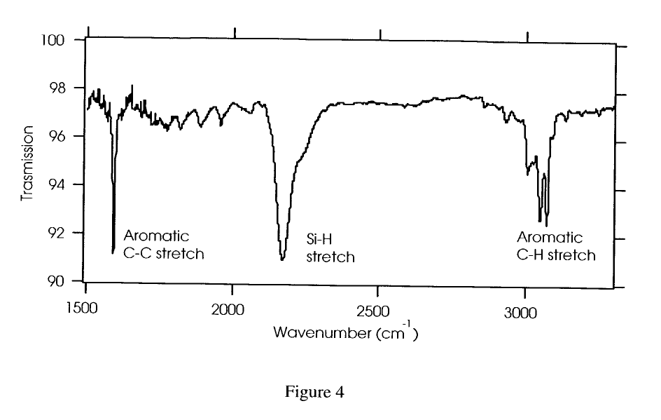

The quality of a coating prepared according to a method of the present invention is illustrated in FIG. 3, which shows an atomic force microscope (AFM) image of a Si(111) surface after coating with phenylsilane at 200 K. The surface is ultraflat, with root-mean-square roughness of only 2.4 Angstroms for the image of 5 micrometers×5 micrometers. This experiment establishes the uniformity of the coating. The water contact angle of the coated surface is 94-100° C., indicating the hydrophobic nature of the coating. The chemical nature of the coating is verified by FTIR, FIG. 4, which shows intact phenyl groups grafted to the surface.

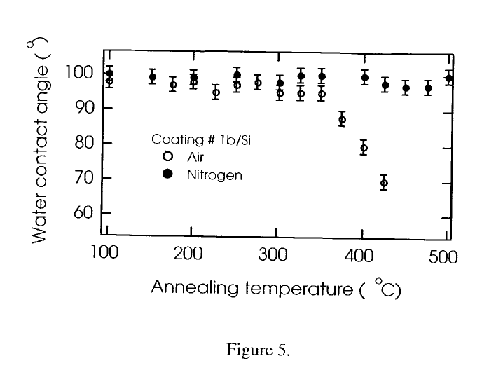

Preferred coatings are thermally stable at elevated temperatures. FIG. 5 shows water contact angles as a function of annealing temperature in air (open circles) and nitrogen (closed circles) for monolayer coating (1b) on the native oxide terminated Si(111) surface. The coating was obtained according to FIG. 1 using dimethyl(perfluorooctyl)silane as the precursor molecule. No change in water contact angles were observed after annealing in nitrogen at temperatures as high as 500° C. For heating in air, change in water contact angle of the surface is seen only at temperatures greater than 350° C.

Objects and advantages of this invention are further illustrated by the following examples, but the particular materials and amounts thereof recited in these examples, as well as other conditions and details, should not be construed to unduly limit this invention.

### EXAMPLES

### Example 1

Referring to FIG. 1, the reactor has a volume of 23 ml (Parr Instrument Company, model 4749). Silicon(111) samples are placed inside the reactor. A total volume of 4 μl of phenylsilane (Sigma Chemical Co.) is added into the reactor under nitrogen. The reactor is sealed under 1 atm of nitrogen. The sealed reactor is placed in an oven and heated to 200° C. After heating for 10 hours, the reactor is removed from the oven, cooled down, opened, and the coated Si(111) samples are removed for characterization by AFM (FIG. 3), FTIR (FIG. 4), and water contact angles.

### Example 2

Referring to FIG. 1, the reactor has a volume of 23 ml (Parr Instrument Company, model 4749). Silicon(111) samples are placed inside the reactor. A total volume of 4 μl of phenylsilane (Sigma Chemical Co.), along with a catalytic amount of water (1 μl), is added into the reactor under nitrogen. The reactor is sealed under 1 atm of nitrogen. The sealed reactor is placed in an oven and heated to 150° C. After heating for 10 hours, the reactor is removed from the oven, cooled down, opened, and the coated Si(111) samples are removed. The coated samples give water contact angles of 100-110°.

### Example 3

Referring to FIG. 1, the reactor has a volume of 23 ml (Parr Instrument Company, model 4749). Silicon(111) samples are placed inside the reactor. A total volume of 4 μl of dimethyl(perfluorooctyl)silane (Sigma Chemical Co.) is added into the reactor under nitrogen. The reactor is sealed under 1 atm of nitrogen. The sealed reactor is placed in an oven and heated to 250° C. After heating for 10 hours, the reactor is removed from the oven, cooled down, opened, and the coated Si(111) samples are removed for characterization by water contact angles (FIG. 5).

### Example 4

Referring to FIG. 2, the reactor has a volume of 23 ml (Parr Instrument Company, model 4749). Silicon and silicon carbide samples are placed in 1 ml of isooctane inside the reactor. A total volume of 10 μl of dimethyl(perfluorooctyl)silane (Sigma Chemical Co.) is added into the liquid phase under nitrogen. The reactor is sealed under 1 atm of nitrogen. The sealed reactor is placed in an oven and heated to 200° C. After heating for 10 hours, the reactor is removed from the oven, cooled down, opened, and the silicon carbide samples are removed from the reactor, rinsed with isotane, and characterized by water contact angles. The water contact angles are 110° for the silicon sample and 90-95° for the silicon carbide sample.

The complete disclosures of the patents, patent documents, and publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

What is claimed is:

1. A method of applying a coating to a surface of a MEMS device; the method comprising:
contacting the surface of the MEMS device with one or more precursor compounds of the formula SiXR₃, wherein each R is independently an organic group, and X is independently selected from the group of Cl and OR′, wherein R′ is independently an alkyl group; and further wherein the one or more precursor compounds are in solution at a temperature of at least about 80° C. upon contacting the surface of the MEMS device.

2. The method of claim 1 wherein the one or more precursor compounds are in solution at a temperature of about 80° C. to about 300° C. upon contacting the surface of the MEMS device.

3. The method of claim 1 wherein each R and R′ independently includes 1-20 carbon atoms.

4. The method of claim 3 wherein at least one R includes up to 20 carbon atoms and the others include up to 2 carbon atoms.

5. The method of claim 3 wherein each R′ is a C1-C4 alkyl moiety.

6. The method of claim 1 wherein at least one R is a fluorinated aliphatic group.

7. The method of claim 6 wherein at least one R is a perfluorinated aliphatic group.

8. The method of claim 1 wherein the coating is a monolayer film.

9. The method of claim 1 wherein the coating is a low energy coating.

10. The method of claim 1 further comprising contacting the surface of the MEMS device with a catalyst in addition to the one or more precursor compounds of the formula SiXR₃.

11. The method of claim 1 wherein the contacting step is carried out at a pressure of more than 1 atm.

12. A method of applying a coating to a surface of a MEMS device; the method comprising:
contacting the surface of the MEMS device with one or more precursor compounds of the formula SiXR₃, each R is independently an organic group, and X is independently selected from the group consisting of Cl and OR′, wherein R′ is independently an alkyl group; and further wherein the one or more precursor compounds are in a vapor phase prior to contacting the surface of the MEMS device.

13. A method of applying a coating to a surface of a MEMS device; the method comprising:
contacting the surface of the MEMS device with one or more precursor compounds of the formula SiXR₃, wherein each R is independently an organic group, and X is independently selected from the group of Cl and OR′, wherein R′ is independently an alkyl group; and further wherein the contacting step occurs prior to packaging of the MEMS device.

14. A method of applying a coating to a surface of a MEMS device; the method comprising:
contacting the surface of the MEMS device with one or more precursor compounds of the formula SiXR₃, wherein each R is independently an organic group, and X is independently selected from the group of Cl and OR′, wherein R′ is independently an alkyl group; and further wherein the coating is a monolayer film.

15. A method of applying a coating to a surface of a MEMS device; the method comprising:
contacting the surface of the MEMS device with one or more precursor compounds of the formula SiHₙR₄₋ₙ, wherein n=1-3 and each R is independently an organic group.

16. The method of claim 15 wherein the coating is a monolayer film.

17. The method of claim 15 wherein the one or more precursor compounds are in a vapor phase prior to contacting the surface of the MEMS device.

18. The method of claim 15 wherein the one or more precursor compounds are in solution at a temperature of at least about 80° C. upon contacting the surface of the MEMS device.

19. The method of claim 18 wherein the one or more precursor compounds are in solution at a temperature of about 80° C. to about 300° C. upon contacting the surface of the MEMS device.

20. The method of claim 15 wherein each R independently includes 1-20 carbon atoms.

21. The method of claim 20 wherein at least one R includes up to 20 carbon atoms and the others include up to 2 carbon atoms.

22. The method of claim 15 wherein at least one R is a fluorinated aliphatic group.

23. The method of claim 22 wherein at least one R is a perfluorinated aliphatic group.

24. The method of claim 15 wherein the contacting step occurs prior to packaging the MEMS device.

25. The method of claim 15 wherein the contacting step occurs simultaneously with packaging the MEMS device.

26. The method of claim 15 further comprising contacting the surface of the MEMS device with a catalyst in addition to the one or more precursor compounds of the formula SiHₙR₄₋ₙ.

27. A method of applying a coating to a surface of a MEMS device; the method comprising contacting one or more MEMS devices with one or more precursor compounds in a sealed container prior to packaging the MEMS device.

28. The method of claim 27 wherein the contacting step is carried out under an inert atmosphere.

29. The method of claim 27 wherein the contacting step is carried out at a temperature of about 25° C. to about 400° C.

30. The method of claim 27 further comprising contacting the one or more MEMS devices with a catalyst in addition to the one or more precursor compounds.

31. A method of applying a coating to a surface of a MEMS device; the method comprising contacting one or more MEMS devices with one or more precursor compounds in a sealed container prior to packaging the MEMS device, wherein the contacting step is carried out at a pressure of more than 1 atm.

32. The method of claim 31 wherein the contacting step is carried out at a pressure of no more than about 200 atm.

33. The method of claim 31 wherein the coating is a low energy coating.

34. The method of claim 31 wherein the coating is a monolayer film.

35. A method of applying a coating to a surface of a MEMS device; the method comprising contacting one or more MEMS devices with one or more precursor compounds in a sealed container prior to packaging the one or more MEMS devices, wherein the one or more precursor compounds are in a vapor phase prior to contacting the one or more MEMS devices.

36. A method of applying a coating to a surface of a MEMS device; the method comprising contacting one or more MEMS devices with one or more precursor compounds in a sealed container prior to packaging the one or more MEMS devices, wherein the one or more precursor compounds are in solution at a temperature of about 80° C. to about 300° C. upon contacting the one or more MEMS devices.

37. A method of applying a coating to a surface of a MEMS device; the method comprising contacting one or more MEMS devices with one or more precursor compounds in a sealed container prior to packaging the one or more MEMS devices, wherein the one or more precursor compounds are of the formula SiXₙR₄₋ₙ, wherein n=1-3, each R is independently an organic group, and each X is independently selected from the group consisting of H, Cl, and OR′, wherein each R′ is independently an alkyl group.

38. A method of applying a coating to a surface of a MEMS device; the method comprising contacting one or more MEMS devices with one or more precursor compounds in a sealed container prior to packaging the one or more MEMS devices, wherein the one or more precursor compounds are of the formula SiXR₃, wherein each R is independently an organic group, and each X is independently selected from the group of Cl and OR′, wherein each R′ is independently an alkyl group.

39. A method of applying a coating to a surface of a MEMS device; the method comprising contacting one or more MEMS devices with one or more precursor compounds in a sealed container prior to packaging the more or more MEMS devices, wherein the one or more precursor compounds are of the formula SiHₙR₄₋ₙ, wherein n=1-3 and each R is independently an organic group.

40. A method of applying a coating to a surface of a MEMS device; the method comprising contacting one or more MEMS devices with one or more precursor compounds in a sealed container prior to packaging the one or more MEMS devices, wherein the precursor compounds are selected from the group consisting of silanes, siloxanes, organic phosphates, alcohols, ketones, aldehydes, alkenes, alkynes, and combinations thereof.
